(19) United States
(12) Patent Application Publication
(10) Pub. No.: US 2025/0298177 A1
(43) Pub. Date: Sep. 25, 2025

(54) POLARIZING PLATE AND OPTICAL DISPLAY APPARATUS COMPRISING THE SAME

(71) Applicant: SAMSUNG SDI CO., LTD., Yongin-si (KR)

(72) Inventors: Woo Jin JEONG, Suwon-si (KR); Tae Hyun LEE, Suwon-si (KR); Mi Ran SEO, Suwon-si (KR); Il Jin KIM, Suwon-si (KR)

(21) Appl. No.: 19/081,756

(22) Filed: Mar. 17, 2025

(30) Foreign Application Priority Data
Mar. 19, 2024 (KR) 10-2024-0037764

(51) Int. Cl. G02B 5/30; G02B 1/14

(52) U.S. Cl. CPC G02B 5/305; G02B 1/14; G02B 5/3083

(57) ABSTRACT

A polarizing plate and an optical display apparatus are disclosed. The polarizing plate includes a polarizer and a barrier layer formed on one surface of the polarizer. The barrier layer includes a cured product of a composition including a polyvinyl alcohol resin, a crosslinking agent, and a water-based ionic material, and the water-based ionic material in the barrier layer is 0.5 wt % to 18 wt % in amount based on a total 100 wt % of the barrier layer.

### CROSS-REFERENCE TO RELATED APPLICATION

The present application claims priority to and the benefit of Korean Patent Application No. 10-2024-0037764, filed on Mar. 19, 2024, in the Korean Intellectual Property Office, the entire disclosure of which is incorporated herein by reference.

### BACKGROUND

### 1. Field

The present disclosure relates to a polarizing plate and an optical display apparatus.

### 2. Description of the Related Art

While light emitting diode displays, including organic light emitting diode displays, are not required to have a polarizing plate, such a light emitting diode display can suffer poor screen quality due to total reflection of external light at a surface of a panel therein. Therefore, the light emitting diode display generally includes a polarizing plate on an upper surface of the panel. The polarizing plate includes a polarizer and a retardation film. Although the retardation film may be a polymer film, a liquid crystal film has recently been used as the retardation film due to the trend toward reduction in thickness of polarizing plates.

The background of the present disclosure is disclosed in Korean Patent Laid-open Publication No. 10-2006-0103451 and the like.

### SUMMARY

An aspect according to embodiments of the present disclosure is directed toward a polarizing plate that does not include a protective layer on at least one surface of a polarizer and includes a barrier layer to prevent or reduce elution of a dichroic material from the polarizer when left under high temperature/humidity conditions for a long period of time.

One aspect of the present disclosure relates to a polarizing plate.

Recently, with the trend toward reduction in thickness of polarizing plates, a method of stacking a barrier layer, instead of a protective layer, on a polarizing plate has been considered. The barrier layer is generally formed by depositing and curing a barrier layer composition, thus allowing it to have a smaller thickness than related art protective layers.

The polarizing plate according to embodiments of the present disclosure includes a polarizer and a barrier layer formed on a surface of the polarizer, wherein the barrier layer includes a cured product of a composition including a polyvinyl alcohol resin, a crosslinking agent, and a water-based ionic material, and the water-based ionic material in the barrier layer is 0.5 wt % to 18 wt % in amount based on a total 100 wt % of the barrier layer.

Another aspect of the present disclosure relates to an optical display apparatus.

The optical display apparatus includes the polarizing plate according to the present disclosure or includes the barrier layer according to the present disclosure.

Embodiments of the present disclosure provide a polarizing plate that does not include a protective layer on at least one surface of a polarizer and includes a barrier layer to prevent or reduce elution of a dichroic material from the polarizer when left under high temperature/humidity conditions for a long period of time.

### BRIEF DESCRIPTION OF THE DRAWINGS

The accompanying drawings are included to provide a further understanding of the present disclosure and are incorporated in and constitute a part of this specification. The drawings illustrate embodiments of the present disclosure and, together with the description, serve to explain principles of the present disclosure.

FIG. 1 is a cross-sectional view of a polarizing plate according to one embodiment of the present disclosure.

FIG. 2 is a cross-sectional view of a polarizing plate according to another embodiment of the present disclosure.

### DETAILED DESCRIPTION

Hereinafter, example embodiments of the present disclosure will be described in more detail with reference to the accompanying drawings to facilitate practice by one having ordinary knowledge in the art. It should be understood that the present disclosure may be embodied in various ways and is not limited to the following embodiments.

In the drawings, portions irrelevant to the description will be omitted for clarity and like components will be denoted by like reference numerals throughout the specification. Lengths, sizes, and the like of components in the drawings are chosen for the purpose of illustrating the present disclosure, and the present disclosure is not limited thereto.

Herein, spatially relative terms, such as “upper” and “lower”, are defined with reference to the accompanying drawings. Thus, it will be understood that “upper surface” can be used interchangeably with “lower surface”. In addition, when an element is referred to as being placed “on” another element, it may be directly placed on the other element, or intervening element(s) may be present. On the other hand, when an element is referred to as being placed “directly on” another element, there are no intervening element(s) therebetween.

The terminology used herein is for the purpose of describing example embodiments and is not intended to limit the present disclosure. As used herein, the singular forms, “a”, “an”, and “the” are intended to include the plural forms as well, unless the context clearly indicates otherwise.

As used herein to represent a specific numerical range, “X to Y” means “greater than or equal to X and less than or equal to Y (X≤ and ≤Y)”.

The present disclosure relates to a polarizing plate including no protective layer on at least one surface of a polarizer. The polarizing plate includes a barrier layer instead of the protective layer. For example, the polarizing plate may have a barrier layer instead of a protective layer on one surface of the polarizing plate, and a protective layer on the opposite surface of the polarizing plate, or the two opposing surfaces of the polarizing plate may each have a barrier layer instead of a protective layer thereon.

Here, the term “protective layer” refers to an optical device (e.g., optical layer) stacked on one surface of the polarizer to protect the polarizer. The protective layer may be a protective film or a protective coating layer. The protective layer may be a liquid crystal layer or a non-liquid crystal layer. The protective layer may have a predetermined range of in-plane retardation at a wavelength of 550 nm or may have no in-plane retardation.

In one embodiment, the protective film may include a suitable optically clear protective film or protective coating layer (e.g., known to those skilled in the art). For example, the protective film may include at least one selected from among cellulose ester resins, such as triacetylcellulose (TAC) and/or the like, cyclic polyolefin (COP) resins, such as amorphous cyclic polyolefin and/or the like, polycarbonate resins, polyester resins, such as polyethylene terephthalate (PET) and/or the like, polyether sulfone resins, polysulfone resins, polyamide resins, polyimide resins, non-cyclic polyolefin resins, poly(meth)acrylate resins, such as poly(methyl methacrylate), polyvinyl alcohol resins, polyvinyl chloride resins, and polyvinylidene chloride resins.

In one embodiment, the barrier layer may be directly formed on the polarizer. Here, “directly formed” means that the barrier layer is formed on the polarizer without any adhesive layer or bonding layer between the polarizer and the barrier layer. For example, the barrier layer may be formed by directly coating or depositing a barrier layer composition described in more detail below on one surface of the polarizer, followed by drying and curing.

In one embodiment, the polarizing plate may include a polarizer, a protective layer stacked on one surface of the polarizer, and a barrier layer stacked on the other surface (e.g., opposite to the one surface with the protective layer thereon) of the polarizer. For example, the polarizing plate may include a polarizer having a first surface and a second surface opposing the first surface. A protective layer is stacked on the first surface of the polarizer, and a barrier layer is stacked on the second surface of the polarizer.

As will be described in more detail below, the barrier layer may be formed by depositing a barrier layer composition onto one surface of the polarizer, followed by curing. Accordingly, the barrier layer has a thin thickness. The polarizer contains a dichroic material, such as iodine and/or the like, to provide polarization performance. Thus, when the polarizing plate is left under high temperature/humidity conditions (e.g., high temperature and high humidity) for a long period of time, the dichroic material, such as iodine and/or the like, can be eluted from the polarizer (e.g., diffused out of the polarizer). The dichroic material eluted from the polarizer can pass through an optical device disposed between the polarizing plate and an optical display panel to which the polarizing plate is attached, thereby causing corrosion of the optical display panel, for example, a substrate. The polarizing plate according to one or more embodiments includes a barrier layer described in more detail below. The polarizing plate prevents or substantially prevents the dichroic material eluted from the polarizer from passing through the barrier layer when left under high temperature/humidity conditions for a long period of time, thereby preventing or reducing corrosion of the substrate. Whether the dichroic material eluted from the polarizer has passed through the barrier layer can be checked by color change. An experimental example for checking the color change is described in more detail below.

Next, a polarizing plate according to one embodiment will be described.

The polarizing plate according to the embodiment includes a polarizer and a barrier layer formed on one surface of the polarizer.

### Barrier Layer

The barrier layer includes a cured product of a composition including a polyvinyl alcohol resin, a crosslinking agent, and a water-based ionic material. In addition, the water-based ionic material is present in an amount of 0.5 wt % to 18 wt % in the barrier layer.

The barrier layer includes a cured product of the composition.

In one embodiment, the cured product may be a thermally cured product. The barrier layer may be prepared by heat curing, for example, heat treatment, of the composition without using light irradiation. Accordingly, the barrier layer allows a UV absorbent to be contained in any layer of the polarizing plate. For example, using heat curing as the curing method for the barrier layer allows UV absorbent to be contained in any layer of the polarizing plate without being damaged by the curing process. The UV absorbent can prevent or reduce damage to light emitting diodes by external light when the polarizing plate is formed on a light emitting diode display.

In one or more embodiments, the barrier layer may include a polyvinyl alcohol resin, a crosslinking agent, and a water-based ionic material. These may be derived from the composition (e.g., as the thermally cured product of the corresponding component of the composition).

The composition is a water-based composition and includes a polyvinyl alcohol resin, a crosslinking agent, a water-based ionic material, and a water-based solvent. The water-based ionic material can be easily dissolved in the water-based solvent to facilitate formation of the barrier layer and can prevent or substantially prevent a dichroic material eluted from the polarizer on a front side of the polarizing plate from passing through the barrier layer.

The water-based ionic material is present in an amount of 0.5 wt % to 18 wt % in the barrier layer. When the water-based ionic material is present in an amount of 0.5 wt % or more in the barrier layer, the water-based ionic material can prevent or substantially prevent eluted dichroic material from passing through the barrier layer when the polarizing plate is left under high temperature/humidity conditions for a long period of time, thereby preventing or reducing corrosion of the substrate. When the water-based ionic material is present in an amount of 18 wt % or less in the barrier layer, the barrier layer does not suffer from any problem, such as deterioration in light transmittance due to an excess of the water-based ionic material, and can be formed on the polarizer with high (e.g., strong) adhesion. For example, the water-based ionic material may be present in an amount of 0.5, 0.6, 0.7, 0.8, 0.9, 1.0, 1.1, 1.2, 1.3, 1.4, 1.5, 1.6, 1.7, 1.8, 1.9, 2.0, 2.1, 2.2, 2.3, 2.4, 2.5, 2.6, 2.7, 2.8, 2.9, 3.0 3.1, 3.2, 3.3, 3.4, 3.5, 3.6, 3.7, 3.8, 3.9, 4.0, 4.1, 4.2, 4.3, 4.4, 4.5, 4.6, 4.7, 4.8, 4.9, 5.0, 5.1, 5.2, 5.3, 5.4, 5.5, 5.6, 5.7, 5.8, 5.9. 6.0, 6.1, 6.2, 6.3, 6.4, 6.5, 6.6, 6.7, 6.8, 6.9, 7.0, 7.1, 7.2, 7.3, 7.4, 7.5, 7.6, 7.7, 7.8, 7.9, 8.0, 8.1, 8.2, 8.3, 8.4, 8.5, 8.6, 8.7, 8.8, 8.9, 9.0, 9.1, 9.2, 9.3, 9.4, 9.5, 9.6, 9.7, 9.8, 9.9, 10.0, 10.1, 10.2, 10.3, 10.4, 10.5, 10.6, 10.7, 10.8, 10.9, 11.0, 11.1, 11.2, 11.3, 11.4, 11.5, 11.6, 11.7, 11.8, 11.9. 12.0. 12.1, 12.2, 12.3, 12.4, 12.5, 12.6, 12.7, 12.8, 12.9, 13.0. 13.1, 13.2, 13.3, 13.4, 13.5, 13.6, 13.7, 13.8, 13.9, 14.0, 14.1, 14.2, 14.3, 14.4, 14.5, 14.6, 14.7, 14.8, 14.9, 15.0, 15.1, 15.2, 15.3, 15.4, 15.5, 15.6, 15.7, 15.8, 15.9, 16.0, 16.1, 16.2, 16.3, 16.4, 16.5, 16.6, 16.7, 16.8, 16.9, 17.0, 17.1, 17.2, 17.3, 17.4, 17.5, 17.6, 17.7, 17.8, 17.9, 18.0 wt %, 0.8 wt % to 17 wt %, or 0.9 wt % to 17 wt %, in the barrier layer.

The water-based ionic material not only dissolves well in the water-based solvent, but also adsorbs dichroic materials, for example, iodine ions, eluted from the polarizer while being dissolved in the water-based solvent, thereby blocking (e.g., finally blocking) permeation of the dichroic materials into the barrier layer. Because the ionic material is contained in a water-based barrier layer composition, the ionic material should be soluble in the water-based solvent. In addition, it is desirable that the ionic material be capable of adsorbing the eluted dichroic materials, for example, iodine ions. Further, it is desirable that the water-based ionic material does not affect curing reaction between the polyvinyl alcohol resin and the crosslinking agent described in more detail below.

The water-based ionic material includes cations and anions, in which the cations can adsorb the eluted iodine ions.

In one embodiment, the water-based cationic material may include an ammonium-based cation and an anion.

In one embodiment, the ammonium-based cation may have a hydroxyl group or an aliphatic or aromatic hydrocarbon group substituted with a hydroxyl group. The ammonium-based cation can facilitate adsorption of the eluted dichroic materials, for example, iodine ions. For example, the water-based ionic material may have at least one hydroxyl group, for example, 1 to 5 hydroxyl groups.

In one embodiment, the water-based cationic material may include a nitrate anion or a sulfate anion. These anions can facilitate adsorption of the eluted dichroic material, for example, iodine ions.

For example, the water-based ionic material may include a compound represented by Formula 1:

R¹R²R³R⁴N⁺X,

where X is a monovalent nitrate anion or a monovalent sulfate anion; and

R¹, R², R³, and R⁴ are each independently a substituted or unsubstituted straight or branched C₁ to C₁₀ alkyl group or a substituted or unsubstituted C₆ to C₂₀ aryl group.

In Formula 1, the carbon number of the alkyl group refers to only the number of carbon atoms constituting a main chain of the straight or branched alkyl group. In Formula 1, the carbon number of the aryl group refers to only the number of carbons constituting the ring (e.g., single ring or fused rings) of the aryl group.

In Formula 1, “substituted” in the expression “substituted or unsubstituted” means that at least one hydrogen atom of a corresponding functional group is substituted with a straight or branched C₁ to C₁₀ alkyl group, a hydroxyl group (OH), a straight or branched C₁ to C₂₀ alkoxyl group, or a substituted amide group. As used herein, “substituted amide group” refers to a functional group represented by Formula 2:

R⁵—C(═O)—NH—*,

where * is a linking site to an element and R⁵ is a straight or branched C₁ to C₂₀ alkyl group.

In an embodiment, in Formula 2, R⁵ is a straight or branched C₁₀ to C₂₀ alkyl group.

In an embodiment, at least one of R¹, R², R³ or R⁴ is a C₁ to C₁₀ alkyl group substituted with a hydroxyl group or a C₆ to C₂₀ aryl group substituted with a hydroxyl group. In an embodiment, at least one of R¹, R², R³ or R⁴ is a C₁ to C₅ alkyl group substituted with a hydroxyl group. Here, the ionic material can be dissolved (e.g., well) in the water-based composition and can facilitate adsorption of the eluted dichroic material.

In an embodiment, at least one of R¹, R², R³ or R⁴ is a C₁ to C₁₀ alkyl group substituted with a C₁ to C₂₀ alkoxy group. In an embodiment, at least one of R¹, R², R³ or R⁴ is a C₁ to C₅ alkyl group substituted with a C₁₀ to C₂₀ alkoxy group.

In an embodiment, at least one of R¹, R², R³ or R⁴ is a C₁ to C₁₀ alkyl group substituted with the substituted amide group. In an embodiment, at least one of R¹, R², R³ or R⁴ is a C₁ to C₅ alkyl group substituted with the substituted amide group.

In an embodiment, X is NO₃⁻ or R—SO₄⁻, where R is a straight or branched C₁ to C₅ alkyl group. In an embodiment, X is NO₃⁻ or CH₃SO₄⁻

In an embodiment, at least one of R¹, R², R³ or R⁴ is a long-chain alkyl group or a long-chain alkoxy group, which may be substituted with a straight or branched C₁₀ to C₂₀ alkyl group or a straight or branched C₁₀ to C₂₀ alkoxy group.

For example, the water-based ionic material may include at least one compound represented by Formula 1-1 or Formula 1-2:

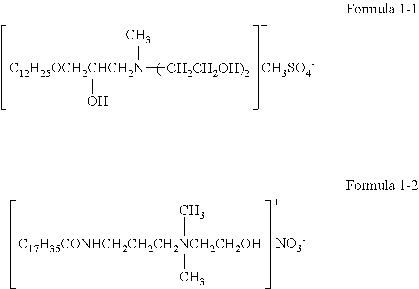

In one embodiment, the water-based ionic material may have a liquid or solid phase, for example, a liquid phase, at room temperature (for example, at 20° C. to 30° C.). For example, the water-based ionic material may be in a liquid phase or a solid phase at a temperature of 20° C. to 30° C.

The water-based ionic material may be present in an amount of 1 part by weight to 20 parts by weight, for example 1, 2, 3, 4, 5, 6, 7, 8, 9, 10, 11, 12, 13, 14, 15, 16, 17, 18, 19, 20 parts by weight relative to the total of 100 parts by weight of the polyvinyl alcohol resin and the crosslinking agent. Within this range, the water-based ionic material may be included in the barrier layer at the suitable amount (e.g., 0.5 wt % to 18 wt % in amount based on a total 100 wt % of the barrier layer).

The polyvinyl alcohol resin may be a vinyl-based polymer, which exhibits good properties in terms of adhesion when the polarizing plate includes a polyvinyl alcohol-based polarizer as a polarizer.

The polyvinyl alcohol resins may include polyvinyl alcohol or derivatives thereof obtained through saponification of vinyl acetate, saponides of copolymers of vinyl acetate and monomers copolymerizable therewith, or modified polyvinyl alcohol resins obtained through acetylation, urethanization, etherification, grafting, or phosphoric acid esterification of polyvinyl alcohol. These materials may be included alone or as a mixture thereof. The copolymerizable monomers may include unsaturated carboxylic acids, such as maleic acid (anhydride), fumaric acid, crotonic acid, itaconic acid, (meth)acrylic acid, and/or the like, or their esters; α-olefins, such as ethylene, propylene, and/or the like; (meth)allyl sulfonic acid; monoalkyl maleate; disulfonic acid soda alkyl maleate; N-methylolacrylamide; acrylamide alkyl sulfonic acid alkali salt; N-vinyl pyrrolidone; N-vinyl pyrrolidone derivatives, and/or the like.

In one embodiment, the polyvinyl alcohol resin may include a polyvinyl alcohol resin containing one or more acetoacetyl groups. The polyvinyl alcohol resin containing one or more acetoacetyl groups can help improve bonding strength of a bonding layer.

In one embodiment, the polyvinyl alcohol resin may have an acetoacetyl group modification degree of 1 mol % to 30 mol %, for example, 1 mol % to 10 mol %. Within these ranges, the polyvinyl alcohol resin can provide sufficient reaction points with the crosslinking agent to exhibit suitable adhesion while improving water resistance of the polarizing plate. A method for preparing the polyvinyl alcohol resin containing acetoacetyl groups is not particularly limited. For example, the polyvinyl alcohol resin containing acetoacetyl groups may be prepared by dispersing the polyvinyl alcohol resin in acetic acid, followed by adding diketene to the resulting mixture, without being limited thereto.

The polyvinyl alcohol resin may have an average degree of polymerization of 100 to 3,000 and an average degree of saponification of 85 mol % to 100 mol %, without being limited thereto. Within these ranges, the polyvinyl alcohol resin can further improve adhesion between the polarizer and the barrier layer.

The polyvinyl alcohol resin may be present in an amount of 1 part by weight to 20 parts by weight, for example, 1 part by weight to 10 parts by weight, relative to 100 parts by weight of the water-based solvent described in more detail below. Within these ranges, the polyvinyl alcohol resin can prevent or substantially prevent a rapid increase in viscosity of the barrier layer composition, thereby securing good processability and easy preparation of a thin barrier layer while allowing strong adhesion of the barrier layer to the polarizer.

The crosslinking agent can secure strong adhesion of the barrier layer to the polarizer by crosslinking the polyvinyl alcohol resin.

The crosslinking agent may be present in an amount of 0.01 parts by weight to 10 parts by weight, for example, 0.01, 0.1, 1, 2, 3, 4, 5, 6, 7, 8, 9, 10 parts by weight, 1, 0.1 parts by weight to 10 parts by weight, relative to 100 parts by weight of the polyvinyl alcohol resin. Within these ranges, the crosslinking agent can further improve adhesion of the barrier layer to the polarizer.

The crosslinking agent may include at least one of an amine group-containing crosslinking agent or a metal-containing crosslinking agent. In an embodiment, the crosslinking agent includes a mixture of the amine group-containing crosslinking agent and the metal-containing crosslinking agent. According to one embodiment, the amine group-containing crosslinking agent may be present in an amount of 50 wt % or more, for example, 50 wt % to 100 wt %, based on a total 100 wt % of the crosslinking agent. According to one embodiment, the metal-containing crosslinking agent may be present in an amount of 50 wt % or more, for example, 50 wt % to 100 wt %, based on a total 100 wt % of the crosslinking agent. According to one embodiment, the mixture of the crosslinking agents may be present in an amount of 95 wt % or more, for example, 99 wt % to 100 wt %.

The amine group-containing crosslinking agent can react with the polyvinyl alcohol resin to allow (e.g., enable) strong adhesion of the barrier layer to the polarizer. The crosslinking agent may contain one or more, for example, two, straight or branched primary amine groups (—NH₂) or secondary amine groups (—NH—), to provide higher bonding strength to a bonding layer. In addition, the crosslinking agent is selected from among a plurality of crosslinking agents used in water-based polyvinyl alcohol bonding agents by taking into account the water-based ionic material described in more detail above.

In one embodiment, the amine group-containing crosslinking agent may include at least one polyethyleneimine crosslinking agent.

The polyethyleneimine crosslinking agent has a primary amine group and/or a secondary amine group and may include straight or branched chain compounds having a secondary amine group and/or a tertiary amine group in the main chain. The primary amine group and/or the secondary amine group can react with functional groups of the polyvinyl alcohol resin, for example, a hydroxyl group or an acetoacetyl group, to improve bonding strength.

The polyethyleneimine crosslinking agent may include a crosslinking agent having ethylene groups (—CH₂CH₂—) linked by a secondary amine group and/or a tertiary amine group and having a primary amine group and/or a secondary amine group at terminal ends thereof (e.g., as known to those skilled in the art).

The amine group-containing crosslinking agent may be present in an amount of 0.01 parts by weight to 10 parts by weight, for example, 0.1 parts by weight to 5 parts by weight, relative to 100 parts by weight of the polyvinyl alcohol resin. Within these ranges, the amine group-containing crosslinking agent can further improve adhesion of the barrier layer to the polarizer.

As the metal-containing crosslinking agent, a zirconium-containing compound may be used. The zirconium-containing compound may include zirconium halides, such as zirconium oxychloride, zirconium hydroxychloride, zirconium tetrachloride, zirconium bromide, and/or the like; zirconium salts of inorganic acids, such as zirconium sulfate, basic zirconium sulfate, zirconium oxynitrate, zirconium oxyacetate, zirconium oxycarbonate, and/or the like; zirconium salts of organic acids, such as zirconium formate, zirconium acetate, zirconium propionate, zirconium caprylate, zirconium stearate, zirconium lactate, zirconium nitrate, zirconium carbonate, zirconium octoate, zirconium citrate, zirconium phosphate, and/or the like; zirconium complex salts, such as ammonium zirconium carbonate, sodium zirconium sulfate, ammonium zirconium acetate, ammonium zirconium carbonate, potassium zirconium carbonate, sodium zirconium oxalate, sodium zirconium citrate, ammonium zirconium citrate, and/or ammonium zirconium lactate, and/or zirconium chelate complexes containing at least one chelate agent as a coordination group. Among these compounds, in one embodiment, the zirconium-containing compound includes a water-soluble zirconium-containing compound, for example, a zirconium oxyhalogenate, zirconium oxyacetate, zirconium sulfate, and/or zirconium oxynitrite. In one embodiment, the zirconium-containing compound includes zirconium oxynitrite or hydrates thereof.

The metal-containing crosslinking agent may be present in an amount of 0.01 parts by weight to 10 parts by weight, for example, 0.1 parts by weight to 5 parts by weight, relative to 100 parts by weight of the polyvinyl alcohol resin. Within these ranges, the metal-containing crosslinking agent can further improve adhesion of the barrier layer to the polarizer.

In the crosslinking agent, the amine group-containing crosslinking agent and the metal-containing crosslinking agent may be present in a weight ratio of 1:0.1 to 1:5, 1:0.1, 1:0.2:1:0.3, 1:0.4, 1:0.5, 1:0.6, 1:0.7, 1:0.8, 1:0.9, 1:1, 1:1.1, 1:1.2, 1:1.3, 1:1.4, 1:1.5, 1:1.6, 1:1.7, 1:1.8, 1:1.9, 1:2, 1:2.1, 1:2.2, 1:2.3, 1:2.4, 1:2.5, 1:2.6, 1:2.7, 1:2.8, 1:2.9, 1:3, 1:3.1, 1:3.2, 1:3.3, 1:3.4, 1:3.5, 1:3.6, 1:3.7, 1:3.8, 1:3.9, 1:4, 1:4.1, 1:4.2, 1:4.3, 1:4.4, 1:4.5, 1:4.6, 1:4.7, 1:4.8, 1:4.9, 1:5, for example, 1:0.5 to 1:3. Within these ranges, the barrier layer composition can easily realize the effects of the barrier layer.

The water-based solvent can facilitate deposition of the barrier layer composition to form a thin barrier layer. The water-based solvent may include water, for example, ultrapure water and/or the like, without being limited thereto. The water-based solvent may be present as a balance amount in the barrier layer composition.

The water-based barrier layer composition may further include one or more suitable additives other than the water-based solvent, the polyvinyl alcohol resin, the crosslinking agent and the water-based ionic material. For example, the additives may include at least one selected from among UV absorbents, heat stabilizers, plasticizers, surfactants, reaction inhibitors, adhesion enhancers, thixotropic agents, conductivity imparting agents, antioxidants, leveling agents, stabilizers, and antistatic agents, without being limited thereto.

The barrier layer may be formed by depositing the water-based barrier layer composition to a predetermined thickness on one surface of the polarizer, followed by thermally curing the composition. For example, heat curing is not limited to a particular method and may be realized by performing, for example, heat treatment at 40° C. to 100° C. for 1 min to 60 min. The heat treatment may be conducted one time or two or more times.

The barrier layer may have a thickness of 10 nm to 500 nm, for example, 50 nm to 200 nm. Within these ranges, the barrier layer can assist in (e.g., contribute to) reduction in thickness of the polarizing plate.

### Polarizer

The polarizer may include any suitable polarizer (e.g., known to those skilled in the art). For example, the polarizer may include a polarizer formed of a polyvinyl alcohol (PVA) resin film or a polypropylene (PP) resin film. For example, the polarizer may be a polyvinyl alcohol-based polarizer containing at least one dichroic material, such as iodine, dichroic dyes, and/or the like, adsorbed onto the polyvinyl alcohol resin film.

The polyvinyl alcohol resin film may have a degree of saponification of 85 mol % to 100 mol %, for example, 98 mol % to 100 mol %. The polyvinyl alcohol resin film may have a degree of polymerization of 1,000 to 10,000, for example, 1,500 to 10,000. Within these ranges of the degree of saponification and the degree of polymerization, the polyvinyl alcohol resin film can be suitably formed into a polarizer. The polarizer may be prepared by suitable methods (e.g., known to those skilled in the art).

The polarizer may have a thickness of 5 μm to 30 μm, for example, 5 μm to 25 μm. Within these ranges, the polarizer can be suitably used in a polarizing plate and can assist in (e.g., contribute to) reduction in thickness of the polarizing plate.

The polarizing plate may further include at least one protective layer.

### Protective Layer

The protective layer may be formed on at least one surface of the polarizer to protect the polarizer or to provide additional functions to the polarizing plate.

The protective layer may include at least one of an optically transparent protective film or an optically transparent protective coating layer.

When the protective layer is of the protective film type or kind, the protective layer may include a protective film formed of an optically clear resin. The protective film may be formed by melt extrusion of the resin. If necessary, the resin may be further subjected to a stretching process. The resin may include at least one selected from among cellulose ester resins, such as triacetylcellulose and/or the like, cyclic polyolefin resins, such as cyclic olefin polymers (COP) and/or the like, polycarbonate resins, polyester resins, such as polyethylene terephthalate (PET) and/or the like, polyether sulfone resins, polysulfone resins, polyamide resins, polyimide resins, non-cyclic polyolefin resins, poly(meth)acrylate resins, such as poly(methyl methacrylate), polyvinyl alcohol resins, polyvinyl chloride resins, and polyvinylidene chloride resins.

When the protective layer is of the protective coating layer type or kind, the protective layer can have good properties in terms of adhesion to the polarizer, transparency, mechanical strength, thermal stability, moisture barrier capacity, and durability. In one embodiment, the protective coating layer as the protective layer may be formed of an actinic radiation-curable resin composition including an actinic radiation-curable compound and a polymerization initiator.

The actinic radiation-curable compound may include at least one selected from among a cationic polymerizable curable compound, a radical polymerizable curable compound, a urethane resin, and a silicone resin. The cationic polymerizable curable compound may be an epoxy compound containing at least one epoxy group in a molecule thereof or an oxetane compound containing at least one oxetane ring in a molecule thereof. The radical polymerizable curable compound may be a (meth)acrylic compound containing at least one (meth)acryloyloxy group in a molecule thereof.

The protective layer may further include one or more suitable additives (e.g., known to those skilled in the art) in addition to the optically transparent resin or actinic radiation-curable compound. The additives may include antioxidants, UV absorbents, ionic conductors, conductivity imparting agents, such as conductive metal oxide particulates, light diffusivity imparting additives, viscosity modifiers, and/or the like.

The protective layer may have a thickness of 5 μm to 200 μm, for example, 20 μm to 120 μm. In an embodiment, the protective layer may have a thickness of 50 μm to 100 μm (in the case of the protective film type) or 5 μm to 50 μm (in the case of the protective coating layer type). Within these ranges, the protective layer can be suitably used in an optical display apparatus.

The protective layer may include a functional coating layer formed on at least one surface thereof, or may be subjected to surface treatment. The functional coating layer may include a hard coating layer, an anti-fingerprint layer, an antireflection layer, a low reflectivity layer, an ultra-low reflectivity layer, and/or an antiglare layer, without being limited thereto. Surface treatment of the protective layer may include corona treatment, without being limited thereto.

The protective layer may be bonded to the polarizer or to an adherend other than the polarizer through a bonding layer. The bonding layer may be formed of a water-based bonding agent or a photocurable bonding agent, without being limited thereto. The water-based bonding agent and the photocurable bonding agent may be any suitable ones (e.g., known to those skilled in the art).

When the protective layer is formed on the polarizer opposite to a first bonding layer, the protective layer may be referred to as an upper protective layer. In such a case, the upper protective layer may include a UV absorbent. The UV absorbent may prevent or substantially prevent damage to optical devices, such as light emitting diodes, in an optical display panel by external light.

The polarizing plate may further include at least one retardation layer. The retardation layer may be present singularly or in plural within the polarizing plate.

### Retardation Layer

The retardation layer can improve screen quality by preventing or substantially preventing reflection of external light through circular polarization of linearly polarized light emitted through the polarizer.

In one embodiment, the retardation layer may have an in-plane retardation (Re) of 225 nm to 350 nm, for example, 225 nm to 300 nm, corresponding to, for example, a λ/2 retardation, at a wavelength of 550 nm. Within these ranges, the retardation layer can achieve improvement in screen quality through reduction in reflectivity to external light.

In another embodiment, the retardation layer may have an in-plane retardation (Re) of 100 nm to 220 nm, for example, 100 nm to 180 nm, corresponding to, for example, a λ/4 retardation, at a wavelength of 550 nm. Within these ranges, the retardation layer can achieve improvement in screen quality through reduction in reflectivity to external light.

In another embodiment, the retardation layer may include a stack of a first retardation layer having an in-plane retardation (Re) of 225 nm to 350 nm, for example, 225 nm to 300 nm, corresponding to, for example, a λ/2 retardation, at a wavelength of 550 nm, and a second retardation layer having an in-plane retardation (Re) of 100 nm to 220 nm, for example, 100 nm to 180 nm, corresponding to, for example, a λ/4 retardation, at a wavelength of 550 nm.

As used herein, “in-plane retardation (Re)” may be calculated according to the Equation: Re=(nx−ny)×d, where nx and ny are the indexes of refraction in the slow axis direction and the fast axis direction of the retardation layer, respectively, and d is the thickness of the retardation layer (unit: nm).

The retardation layer may have a thickness of 0.01 μm to 30 μm, for example, 1 μm to 10 μm. Within these ranges, the retardation layer can assist in (e.g., contribute to) reduction in thickness of the polarizing plate while achieving target retardation.

The retardation layer may be of a film or coating layer type or kind. In an embodiment, the retardation layer is a coating layer for thickness reduction of the polarizing plate.

The retardation layer may be a liquid crystal layer or a non-liquid crystal layer.

The film type or kind retardation layer may be prepared from a suitable resin (e.g., known to those skilled in the art). For example, the film type or kind retardation layer may be formed of at least one selected from among cellulose ester resins including triacetylcellulose (TAC) and/or the like, cyclic polyolefin (COP) resins including amorphous cyclic polyolefin and/or the like, polycarbonate resins, polyester resins including polyethylene terephthalate (PET) and/or the like, polyether sulfone resins, polysulfone resins, polyamide resins, polyimide resins, non-cyclic polyolefin resins, polyacrylate resin including poly(methyl methacrylate) resins and/or the like, polyvinyl alcohol resins, polyvinyl chloride resins, and polyvinylidene chloride resins.

The coating layer type or kind retardation layer may be a non-liquid crystal layer and may include a coating layer formed of a thermosetting composition, an actinic radiation-curable composition, or a coating layer formed of a liquid crystal composition.

The polarizing plate may include at least one adhesive layer. The adhesive layer may be present singularly or in plural within the polarizing plate.

### Adhesive Layer

The adhesive layer may be used to adhesively bond the barrier layer to the retardation layer or to adhesively bond the barrier layer to the protective layer.

In one embodiment, the adhesive layer may be a pressure sensitive adhesive (PSA) layer. For example, the pressure sensitive adhesive layer may include a cured product of a composition including an adhesive resin and a curing agent.

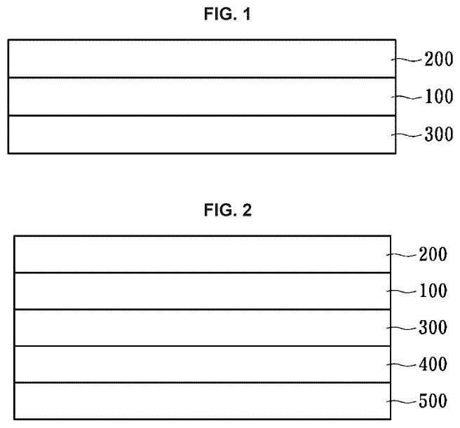

FIG. 1 is a cross-sectional view of a polarizing plate according to one embodiment. Referring to FIG. 1, the polarizing plate may include: a polarizer 100; a protective layer 200 stacked on an upper surface of the polarizer 100; and a barrier layer 300 formed on a lower surface of the polarizer 100.

FIG. 2 is a cross-sectional view of a polarizing plate according to another embodiment. Referring to FIG. 2, the polarizing plate may include a polarizer 100; a protective layer 200 formed on an upper surface of the polarizer 100; and a barrier layer 300, an adhesive layer 400, and a retardation layer 500 sequentially stacked on a lower surface of the polarizer 100.

In some embodiments, the protective layer 200 may be bonded to the polarizer 100 by a bonding layer. The bonding layer may be formed by a water-based bonding agent or a photocurable bonding agent.

An optical display apparatus according to the present disclosure includes a polarizing plate according to the present disclosure.

For example, the optical display apparatus may include a light emitting display including an organic light emitting display, or the like. For example, the optical display apparatus may include a flexible optical display apparatus.

Next, the present disclosure will be described in more detail with reference to some examples. However, it should be noted that these examples are provided for illustration purpose only and are not to be construed in any way as limiting the present disclosure.

### Example 1

### Preparation of Polarizer

A polyvinyl alcohol film (PS #60, Degree of polymerization: 2800, thickness: 60 μm, Kuraray) was dyed in an aqueous solution containing 0.3% of iodine at a temperature of 55° C. The dyed film was uniaxially stretched to 6.0 times an initial length thereof in the MD of the film. The stretched polyvinyl alcohol film was dipped in an aqueous solution containing 3 wt % of boric acid and 2 wt % of potassium iodide for color correction. The resulting product was dried at 50° C. for 4 min, thereby providing a polarizer (thickness: 25 μm, light transmittance: 45%).

### Preparation of Water-Based Barrier Layer Composition

A polyvinyl alcohol resin was dissolved in 100 parts by weight of water at 95° C. while stirring for 60 min. The resulting solution was cooled (e.g., completely cooled) to room temperature and then mixed with a mixture of a zirconium-containing curing agent and an amine curing agent, thereby preparing a mixture of the polyvinyl alcohol resin, the zirconium-containing curing agent, and the amine curing agent.

The polyvinyl alcohol resin was Z200 available from Mitsubishi Chemical Co. Ltd.

The zirconium-containing curing agent was Zircosol Zn (ZrO(NO₃)₂) available from Daiichi Kigenso Kagaku Kogyo Co., Ltd.

The amine curing agent was SP018 (polyethyleneimine crosslinking agent) available from Nippon Shokubai Co., Ltd.

The mixture of the polyvinyl alcohol resin, the zirconium-containing curing agent, and the amine curing agent included 100 parts by weight of the polyvinyl alcohol resin, 5 parts by weight of the zirconium-containing curing agent, and 5 parts by weight of the amine curing agent in terms of solid content.

A water-based barrier layer composition was prepared by adding 20 parts by weight of N,N-bis(2-hydroxyethyl)-N-(3′-dodecyloxy-2′-hydroxypropyl)methyl ammonium methyl sulfate of Formula 1-1 to 100 parts by weight of the mixture of the polyvinyl alcohol resin, the zirconium-containing curing agent, and the amine curing agent.

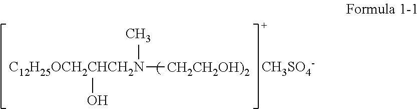

Table 1 below shows the content of the compound of Formula 1 relative to 100 parts by weight of a mixture including 100 parts by weight of the polyvinyl alcohol resin, 5 parts by weight of the zirconium-containing curing agent, and 5 parts by weight of the amine curing agent.

In Table 1, “-” indicates that the corresponding component is not present.

### Manufacture of Polarizing Plate

3 parts by weight of a polyvinyl alcohol resin (Z200, polyvinyl alcohol modified with an acetoacetyl group, average polymerization degree: 1,200, average saponification degree: 99 mol %, acetoacetyl group modification degree: 5 mol %, Mitsubishi Chemical Co., Ltd.) was dissolved in 100 parts by weight of water at 95° C. while stirring for 60 min. The resulting solution was cooled (e.g., completely cooled) to room temperature, followed by adding an amine crosslinking agent (SP018, solid content: 40 wt %, polyethyleneimine crosslinking agent, Nippon Shokubai Co., Ltd) to the resulting solution, thereby preparing a bonding agent. The polyethyleneimine crosslinking agent was present in an amount of 1 part by weight relative to 100 parts by weight of the polyvinyl alcohol resin in terms of solid content.

The prepared bonding agent was deposited to a predetermined thickness on an upper surface of the polarizer and a lower surface of a COP film (with a hard coating layer formed on an upper surface thereof, thickness: 28 μm, Zeon Co., Ltd.) was attached to the upper surface of the polarizer by the bonding agent and was dried in an oven at 50° C. for 1 min and at 85° C. for 3 min to bond the COP film to the upper surface of the polarizer.

The prepared water-based barrier layer composition was deposited to a predetermined thickness on a lower surface of the polarizer, followed by attaching a non-saponified triacetylcellulose film (thickness: 40 μm, Normal TAC) thereto.

Then, the barrier layer composition was dried at 80° C. for 3 min and the non-saponified triacetylcellulose film was removed therefrom, thereby preparing a polarizing plate in which the COP film (thickness: 28 μm), the adhesive layer (thickness: 3 μm), the polarizer (thickness: 25 μm), and the barrier layer (thickness: 100 nm) were sequentially stacked in the stated order.

### Examples 2 to 5 and Comparative Example 1

Polarizing plates were prepared in the same manner as in Example 1 except that the amount of N,N-bis(2-hydroxyethyl)-N-(3′-dodecyloxy-2′-hydroxypropyl)methylammonium methyl sulfate of Formula 1-1 relative to 100 parts by weight of the mixture of the polyvinyl alcohol resin, the zirconium-containing curing agent, and the amine curing agent in an aqueous composition was changed as listed in Table 1.

### Example 6

A polarizing plate was prepared in the same manner as in Example 1 except that 20 parts by weight of stearamidopropyldimethyl-2-hydroxyethyl ammonium nitrate of Formula 1-2 was used instead of the compound of Formula 1.

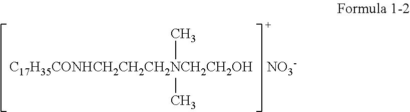

### Examples 7 to 10 and Comparative Example 2

Polarizing plates were prepared in the same manner as in Example 6 except that the amount of stearamidopropyldimethyl-2-hydroxyethyl ammonium nitrate of Formula 1-2 relative to 100 parts by weight of the mixture of the polyvinyl alcohol resin, the zirconium-containing curing agent, and the amine curing agent in the water-based composition was changed as listed in Table 1.

### Comparative Example 3

A polarizing plate was prepared in the same manner as in Example 1 except that the compound of Formula 1-1 was not used.

The compositions of the polarizing plates prepared in Examples and Comparative Examples are shown in Table 1 and the polarizing plates of Examples and Comparative Examples were evaluated as to color change.

Specimens were prepared by forming a pressure-sensitive adhesive layer (acrylic PSA) on a lower surface of the polarizing plate, followed by attaching a glass plate thereto through the pressure-sensitive adhesive layer. The prepared specimens were placed in a chamber under constant temperature/humidity conditions of 60° C. and 95% RH (relative humidity) for 500 hours. The barrier layer, the pressure sensitive adhesive layer, and the glass plate were evaluated as to whether their color was changed to purple due to iodine eluted from the polarizer. A specimen with no color change was rated as ⊚, a specimen allowing partial color change and still suitable for use was rated as ∘, a specimen allowing partial color change and unsuitable for use was rated as Δ, and a specimen allowing overall color change (e.g., significant color change in the barrier layer and/or the pressure sensitive layer) was rated as x.

TABLE 1

| | | | | | | | | | | | Comparative | | |
|---|---|---|---|---|---|---|---|---|---|---|---|---|---|
| | Example | | | | | | | | | | Example | | |
| | 1 | 2 | 3 | 4 | 5 | 6 | 7 | 8 | 9 | 10 | 1 | 2 | 3 |
| Mixture | 100 | 100 | 100 | 100 | 100 | 100 | 100 | 100 | 100 | 100 | 100 | 100 | 100 |
| (parts by | | | | | | | | | | | | | |
| weight) | | | | | | | | | | | | | |
| Formula 1-1 | 20 | 10 | 5 | 2.5 | 1 | — | — | — | — | — | 25 | — | — |
| (parts by | | | | | | | | | | | | | |
| weight) | | | | | | | | | | | | | |
| Formula 1-2 | — | — | — | — | — | 20 | 10 | 5 | 2.5 | 1 | — | 25 | — |
| (parts by | | | | | | | | | | | | | |
| weight) | | | | | | | | | | | | | |
| Formula 1-1 | 16.6 | 9.09 | 4.76 | 2.44 | 0.99 | 16.6 | 9.09 | 4.76 | 2.44 | 0.99 | 20 | 20 | 0 |
| or 1-2 in | | | | | | | | | | | | | |
| barrier | | | | | | | | | | | | | |
| layer (wt %) | | | | | | | | | | | | | |
| Color change | ⊚ | ⊚ | ⊚ | ⊚ | ⊚ | ⊚ | ⊚ | ⊚ | ◯ | ◯ | Δ | Δ | X |

In Table 1, “mixture” means a mixture of a polyvinyl alcohol resin, a zirconium-containing crosslinking agent, and an amine crosslinking agent.

As shown in Table 1, it can be seen that the polarizing plates according to the present disclosure did not suffer from color change by replacing a protective layer with a barrier layer on at least one surface of the polarizer and by preventing or substantially preventing elution of a dichroic material from the polarizer after being left at high temperature/humidity conditions for a long period of time.

On the other hand, it can be seen that the polarizing plate of Comparative Example 3, free from a water-based ionic material, suffered from overall (or significant) color change and failed to provide the same effects as the polarizing plates of Examples. The polarizing plates of Comparative Examples 1 and 2, containing greater than 18 wt % of the water-based ionic material, suffered from (e.g., unsatisfactory) color change, as compared with Examples 1 and 2.

As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. When phrases such as “at least one of A, B, and C,” “at least one of A, B, or C,” “at least one selected from a group of A, B, and C,” or “at least one selected from among A, B, and C” are used to designate a list of elements A, B, and C, the phrase may refer to any and all suitable combinations or a subset of A, B, and C, such as A, B, C, A and B, A and C, B and C, or A and B and C.

used herein, the terms “use,” “using,” and “used” may be considered synonymous with the terms “utilize,” “utilizing,” and “utilized,” respectively. It is to be understood that, although the terms “first,” “second,” “third,” etc., may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

It should be understood that various modifications, changes, alterations, and equivalent embodiments can be made by those skilled in the art without departing from the spirit and scope of the disclosure. The technical scope of the present disclosure should be defined by the appended claims, and equivalents thereof.

What is claimed is:

1. A polarizing plate comprising:
a polarizer and
a barrier layer on one surface of the polarizer,
wherein the barrier layer comprises a cured product of a composition comprising a polyvinyl alcohol resin, a crosslinking agent, and a water-based ionic material, and
the water-based ionic material in the barrier layer is 0.5 wt % to 18 wt % in amount based on a total 100 wt % of the barrier layer.

2. The polarizing plate as claimed in claim 1, wherein the water-based ionic material in the composition is 1 part by weight to 20 parts by weight based on a total 100 parts by weight of the polyvinyl alcohol resin and the crosslinking agent.

3. The polarizing plate as claimed in claim 1, wherein the water-based ionic material is in a liquid phase at a temperature of 20° C. to 30° C.

4. The polarizing plate as claimed in claim 1, wherein the water-based ionic material comprises an ammonium-based cations and an anion.

5. The polarizing plate as claimed in claim 4, wherein the ammonium-based cation has a hydroxyl group or an aliphatic or aromatic hydrocarbon group substituted with a hydroxyl group.

6. The polarizing plate as claimed in claim 4, wherein the anion comprises a nitrate anion or a sulfate anion.

7. The polarizing plate as claimed in claim 1, wherein the water-based ionic material comprises a compound represented by Formula 1:
R¹R²R³R⁴N⁺X,
where X is a monovalent nitrate anion or a monovalent sulfate anion; and
R¹, R², R³, and R⁴ are each independently a substituted or unsubstituted straight or branched C₁ to C₁₀ alkyl group or a substituted or unsubstituted C₆ to C₂₀ aryl group.

8. The polarizing plate as claimed in claim 7, wherein at least one of R¹, R², R³ or R⁴ in Formula 1 is a C₁ to C₁₀ alkyl group substituted with a hydroxyl group or a C₆ to C₂₀ aryl group substituted with a hydroxyl group.

9. The polarizing plate as claimed in claim 7, wherein at least one of R¹, R², R³ or R⁴ in Formula 1 is substituted with a straight or branched C₁₀ to C₂₀ alkyl group or a straight or branched C₁₀ to C₂₀ alkoxy group.

10. The polarizing plate as claimed in claim 1, wherein the water-based ionic material comprises at least one compound represented by Formula 1-1 or Formula 1-2

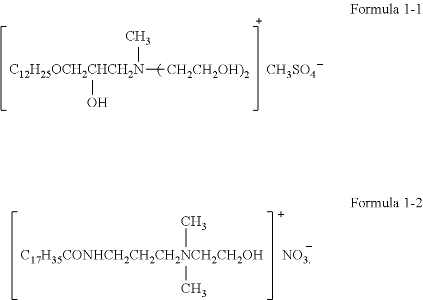

11. The polarizing plate as claimed in claim 1, wherein the crosslinking agent comprises at least one of an amine group-containing crosslinking agent or a metal-containing crosslinking agent.

12. The polarizing plate as claimed in claim 1, wherein the composition comprises:
100 parts by weight of the polyvinyl alcohol resin,
0.01 parts by weight to 10 parts by weight of the crosslinking agent relative to 100 parts by weight of the polyvinyl alcohol resin, and
1 part by weight to 20 parts by weight of the water-based ionic material relative to a total of 100 parts by weight of the polyvinyl alcohol resin and the crosslinking agent.

13. The polarizing plate as claimed in claim 1, wherein the composition is a water-based composition.

14. The polarizing plate as claimed in claim 1, wherein the barrier layer is directly on the polarizer.

15. The polarizing plate as claimed in claim 1, further comprising: at least one of a protective layer, a retardation layer, or an adhesive layer.

16. An optical display apparatus comprising the polarizing plate as claimed in claim 1.
